(19) United States
(12) Patent Application Publication
(10) Pub. No.: US 2009/0217126 A1
(43) Pub. Date: Aug. 27, 2009

(54) GENERATION OF TANNER GRAPHS FOR SYSTEMATIC GROUP CODES FOR EFFICIENT COMMUNICATION

(76) Inventors: Manik Raina, Bangalore (IN); Viswanath Ganapathy, Bangalore (IN); Ranjeet Patro, Bangalore (IN); Chandrashekhara PS Thejaswi, Tempe, AZ (US)

Correspondence Address: HONEYWELL INTERNATIONAL INC.;PATENT SERVICES, 101 COLUMBIA ROAD, P O BOX 2245, MORRISTOWN, NJ, 07962-2245, US

(21) Appl. No.: 12/109,261

(22) Filed: Apr. 24, 2008

Related U.S. Application Data
(60) Provisional application No. 60/925,938, filed on Apr. 24, 2007.

(51) Int. Cl. H03M 13/05; G06F 11/10

(52) U.S. Cl. 714/752; 714/E11.032

(57) ABSTRACT

A computer implemented method of communicating includes receiving systematic group codes representative of one or more messages. A Tanner graph is used to decode such systematic group codes. A method of forming a communication decoder includes obtaining a dual code for a systematic group code, obtaining a Tanner graph from the dual code, and reducing vertex complexity of the Tanner graph to provide a decoding Tanner graph for the communication decoder.

### CLAIM OF PRIORITY

This patent application claims the benefit of priority, under 35 U.S.C. Section 119(e) to U.S. Provisional Patent Application Ser. No. 60/925,938, entitled “Generation of Tanner Graphs for Systematic Group Codes for Efficient Communication”, filed on Apr. 24, 2007, which is incorporated herein by reference in its entirety

### BACKGROUND

Block group codes are widely used in block-coded modulation schemes. Block-coded modulation schemes are used in communications to provide transmission redundancy in data to ensure data is correctly received. The codes are then decoded when received to correctly reconstruct the data. The type of code may be selected during design of a communication system. A code with higher redundancy may be selected for environments with significant noise and reflections to ensure accurate communications. Similarly, other codes may be selected in other environments with varying degrees of redundancy.

Decoding of group codes is important. Prior method of decoding group codes may be complex and slow. Efficient devices and method for decoding group codes are needed.

### BRIEF DESCRIPTION OF THE DRAWINGS

FIG. 1 is a graph representation of a selected code according to an example embodiment.

FIG. 2 is a Tanner graph of a selected systematic group code according to an example embodiment.

FIG. 3 is a flowchart illustrating a method of generating a Tanner graph for a systematic group code according to an example embodiment.

FIG. 4 is a flowchart illustrating a method of decoding systematic group codes using a Tanner graph according to an example embodiment.

FIG. 5 is a flowchart illustrating a method of generating a Tanner graph for a systematic group code including reducing the complexity of the Tanner graph according to an example embodiment.

FIG. 6 is a block diagram of a computer system for implementing methods of generating Tanner graphs for systematic group codes for efficient communication according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software or a combination of software and human implemented procedures in one embodiment. The software may consist of computer executable instructions stored on computer readable media such as memory or other type of storage devices. The term “computer readable media” is also used to represent any means by which the computer readable instructions may be received by the computer, such as by different forms of wired or wireless transmissions. Further, such functions correspond to modules, which are software, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system.

A device and method for obtaining a Tanner graph representation of systematic group codes is described. An introduction to block group codes is first provided, followed by a description of Tanner graphs, and a method of construction of them for a systematic group code. The method is then compared in computational complexity to that of existing techniques.

Block group codes are widely used in block-coded modulation schemes. Block-coded modulation schemes are used in communications to provide transmission redundancy in data to ensure data is correctly received. The codes are then decoded when received to correctly reconstruct the data. The type of code may be selected during design of a communication system. A code with higher redundancy may be selected for environments with significant noise and reflections to ensure accurate communications. Similarly, other codes may be selected in other environments with varying degrees of redundancy. The construction of these codes is important because, if sets with more than two signals are used for transmission, then group structures (rather than field like structures) match the relevant distance measure of a given channel.

A type of graph which may be used to specify and decode codes is the Tanner graph. In one embodiment, Tanner graphs are used to decode the received codewords iteratively. Such Tanner graph based iterative decoding is advantageous in terms of transmission power and computational complexity.

In one embodiment, a length n trim group code over a group G is such that the projection of the code over any coordinate iε[1, n] consists of every element of G. A method to determine the Tanner graph representation of a general group code is described. The method may be outlined as follows. Given a known group code G (which is isomorphic to Z_{g1}×Z_{g2}× . . . Z_{gn}), determine a trim group code G′ which is isomorphic to G and should be isomorphic to Z_{b1}× . . . Z_{bn} such that b₁|g₁, b₂|g₂, . . . , bₙ|gₙ. Then, the Tanner Graphs of G and G′ are isomorphic. This approach is computationally tractable if the Tanner graph of the trim isomorph G′ is already known or can be easily evaluated. Further, the task of determining which isomorph satisfying the above conditions is trim may require enumerating all the codewords and testing for trimness. Given a trim isomorph, the process of determining which elements of Gⁿ are isomorphic to every element of the trim isomorph would require a brute force method.

Systematic group codes are a type of group code. In one embodiment, efficient polynomial time algorithms are used to obtain the Tanner graphs of systematic group codes.

The notion of group codes and systematic group codes is first introduced. The notion of homomorphisms which define a systematic group code is introduced. How these homorphisms form a generator matrix for the code is stated. Then, a dual code for a systematic group code is described. A discussion on how to obtain a dual of a systematic group code, given it's generator matrix follows. Since the defining homomorphisms of the code are assumed to be known, the dual code can be obtained easily in polynomial time without having to rely on brute force search. Tanner graphs are introduced, as is their use for decoding. A method to obtain the Tanner graph from the dual code is described. A method to reduce the vertex complexity of the resulting graph is discussed. A discussion on the computational complexity of the method follows.

Group Codes

Let G be a finite abelian group. The subgroups of Gⁿ are called n length group codes. A group code of length n can be seen as a linear code of length mn over GF(p). Further, a generator matrix Ψ for such a code using endomorphisms over [symbol] _{1<i<m}Zₚ can be constructed. Ψ is a k×n matrix of endomorphisms where ψ_{i,j} represents the i, j'th entry of the matrix such that ψ_{i,j}: [symbol] _{1≦l≦n}Zₚ→ [symbol] _{1≦l≦n}Zₚ. This generator matrix can be used like the generator matrices of block linear codes over fields for tasks such as generating the codewords, given the information set etc.

A (n, k) systematic group code C is a code over Gⁿ of order |G|^{k} defined by n−k homomorphisms {φj}, such that 1≦j≦(n−k). The codewords of C can be written as

(x₁, . . . , xₖ,φ₁(x₁, . . . , xₖ),φ₂(x₁, . . . , xₖ), . . . , φₙ₋ₖ(x₁ . . . , xₖ)).

In the above equation, x₁, . . . , xₖ are the information symbols and xₖ₊ⱼ=φⱼ(x₁, . . . , xₖ). φj is a group homomorphism from G^{k} to G. By the definition of the homomorphism φ, the above expression can be rewritten as

xₖ₊ⱼ=⊕_{i≦l≦k}φⱼ(e, . . . , xₗ, . . . , e) (1)

Since φj(e, . . . , x₁, . . . , e)εG, φj (e, . . . , x₁, . . . , e) can be expressed as ψ_{1,j}(x₁), where ψ_{i,j} are endomorphisms over G. Hence,

xₖ₊ⱼ=⊕_{i≦l≦k}ψ_{i,j}(xᵢ) (2)

Therefore for systematic codes, the generator matrix can be written as G=[I|ψ] where

$$Ψ = ( \begin{matrix}{ψ}_{1 , 1} , … , {ψ}_{1 , n - k} \\ {ψ}_{2 , 1} , … , {ψ}_{2 , n - k} \\ ⋮ \\ {ψ}_{k , 1 } , … , {ψ}_{k , n - k}\end{matrix} ) \qquad ( 3 )$$

Codewords are formed as

(x₁, . . . , xₙ)=[x₁, . . . , xₖ]G (4)

Since any finite abelian group can be expressed as G≡C_{d}_{₁} [symbol] C_{d}_{₂} [symbol] . . . C_{d}_{ₘ}, any element of G can be written in terms of the m generators, {g1, . . . , gm}. Any element of G can be written as

x=⊕_{1≦i≦m}x_{β,i}gᵢ (5)

Now, let us consider the endomorphisms ψ_{i,j.} themselves, let

ψ(gᵢ)= [symbol] _{1≦j≦m}α_{i,j}gⱼ (6)

Then, can be written as

$$ψ = ( \begin{matrix}{α}_{1 , 1} , … , {α}_{1 , m} \\ ⋮ \\ ⋮ \\ {α}_{m , 1} , … , {α}_{m , m}\end{matrix} ) \qquad ( 7 )$$

Then, using equation (5) and equation (6), ψ(x) can be written as

$$ψ ( x ) = {⊗}_{1 \leq h \leq m} \{ {\sum }_{1 \leq i \leq m} {x}_{β , h} {α}_{i , h} mod {d}_{h} \} {g}_{h} \qquad ( 8 )$$

The Dual of a Systematic Group Code

As shown above, any systematic group code can be represented by a matrix of endomorphisms which form its generator matrix. Given any group code C, its corresponding dual code would be represented as C^{⊥}. Every codeword in C^{⊥} and C would be orthogonal to one another. Since only one binary operation [symbol] is defined in a group, we have to rely on the group of characters to define orthogonality. Character theory of groups may be used to define what would constitute a dual code of a given group code. Let x=(x₁, . . . , xₙ)εC and y=(y₁, . . . , yₙ)εC^{⊥}. The inner product of x and y is defined as (y,x)=Π_{1≦i≦n}ηₓ_{ᵢ}(yᵢ)=e*. ηₓ_{ᵢ} is the character of G corresponding to x and e* is the identity element of the group of n'th roots of unity in an appropriate field. Also, ηₓ_{ᵢ}(y_{β})=Πₕ₌₁^{m} λₕ^{x}^{_{i,b}}^{y}^{_{β,h}} where λₕ is the dₕ 'th root of unity. The inner product (y, x) is equal to

$${λ}_{m}^{{\sum }_{i = 1}^{k} {\sum }_{j = 1}^{n - k} {\sum }_{h = 1}^{m} {\sum }_{l = 1}^{m} ( {d}_{m} / {d}_{h} ) {y}_{k + j , l} [ {α}_{j , i}^{*} ( l , h ) + {α}_{j , i} ( h , l ) ] {x}_{i , h}}$$

Suppose a generator matrix G, as specified in equation (3) is taken and from it, a matrix G^{⊥} is generated such that ψ^{⊥}(I,j)=ψ(j, i). It can be shown that the codes generated by G and G^{⊥} are duals of one another.

### Example 1

### A (3,2) Systematic Code

Consider the generator matrix of a systematic group code isomorphic to Z₂×Z₄ as shown

$$G = ( \begin{matrix}( \begin{matrix}10 \\ 01\end{matrix} ) & ( \begin{matrix}00 \\ 00\end{matrix} ) & ( \begin{matrix}12 \\ 13\end{matrix} ) \\ ( \begin{matrix}00 \\ 00\end{matrix} ) & ( \begin{matrix}10 \\ 01\end{matrix} ) & ( \begin{matrix}02 \\ 11\end{matrix} )\end{matrix} ) \qquad ( 10 )$$

{10, 01} is selected as the two generators of Z₂×Z₄. Denote that g₁=10 and g₂₌01. Hence, any element mεZ₂×Z₄ can be written as m₁g₁⊕m₂g₂.

The information set of this code is of the form (x₁, x₂), where x₁εZ₂×Z₄. The codewords can be obtained by evaluating (x₁, x₂)G. The resulting code is of the form (x₁, x₂, x₃) and is enumerated in Table 1.

For example, if G is defined as in equation (10), the generator of the dual code is obtained as shown below

$${G}^{⊥} = ( \begin{matrix}12 \\ 11\end{matrix} ) ( \begin{matrix}02 \\ 13\end{matrix} ) ( ( \begin{matrix}10 \\ 01\end{matrix} ) ) \qquad ( 11 )$$

This is a (3, 1) code whose codewords are given in Table 2. To illustrate the duality of the two codes in the example, compute the inner product (624, 125), where 624 εC^{⊥} and 125 εC. The codewords are resolved into the elements of Z₂×Z₄. 624=12 02 10 and 125=01 02 11. Since d₁=2, λ₁ is chosen as the square root of unity, −1. Similarly, as d₂=4, λ₂ is chosen to be the fourth root of unity, i. The inner product of the codeword is (−1)^{1.0}(i)^{2.1}(−1)^{0.0}(i)^{2.2}(−1)^{1.1}(i)^{0.1}, which evaluates to i²i⁴(−1)=1. Hence, the two codewords are duals.

TABLE 1
Information Set (IS) and Codewords (CW)
for the Code C generated by Equation(10)

| IS | CW | IS | CW | IS | CW | IS | CW |
|---|---|---|---|---|---|---|---|
| 00 | 000 | 10 | 107 | 20 | 202 | 30 | 305 |
| 01 | 015 | 11 | 110 | 21 | 217 | 31 | 312 |
| 02 | 022 | 12 | 125 | 22 | 220 | 32 | 327 |
| 03 | 037 | 13 | 132 | 23 | 235 | 33 | 330 |
| 04 | 042 | 14 | 145 | 24 | 242 | 34 | 347 |
| 05 | 057 | 15 | 152 | 25 | 255 | 35 | 350 |
| 06 | 060 | 16 | 167 | 26 | 262 | 36 | 365 |
| 07 | 075 | 17 | 170 | 27 | 277 | 37 | 372 |
| 40 | 406 | 50 | 501 | 60 | 604 | 70 | 703 |
| 41 | 417 | 51 | 516 | 61 | 611 | 71 | 714 |
| 42 | 424 | 52 | 523 | 62 | 626 | 72 | 721 |
| 43 | 431 | 53 | 534 | 63 | 633 | 73 | 736 |
| 44 | 444 | 54 | 543 | 64 | 646 | 74 | 741 |
| 45 | 451 | 55 | 554 | 65 | 653 | 75 | 756 |
| 46 | 466 | 56 | 561 | 66 | 664 | 76 | 763 |
| 47 | 473 | 57 | 576 | 67 | 671 | 77 | 774 |

TABLE 2
Information Set (IS) and Codewords (CW) for
the Code C^{⊥} generated by Equation(11)

| IS | CW | IS | CW | IS | CW | IS | CW |
|---|---|---|---|---|---|---|---|
| 0 | 000 | 1 | 571 | 2 | 222 | 3 | 753 |
| 4 | 624 | 5 | 353 | 6 | 406 | 7 | 177 |

Tanner Graphs

Tanner graphs are a means of recursively specifying constraints which specify a code. This may be done in one embodiment by means of a bipartite graph where one category of nodes represent the digits of the codewords (called the digit nodes) and the other category of nodes represent the constraints which the digits of the codewords obey. Such a graph representation of codes comes very naturally and exploits the soft decision information, leading to savings in transmitted power and decoding complexity. Decoding by exploiting Tanner graphs extensively make use of iteration and parallelism to greatly increase decoding efficiency.

### Example 2

### A Simple Tanner Graph

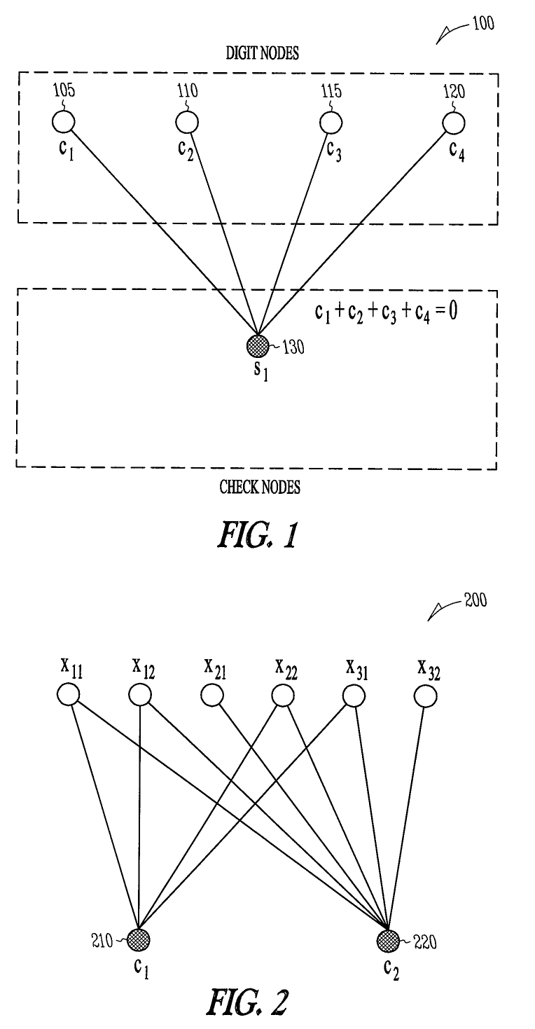

As an example, suppose Z₂ codes of length 4 such that all their codewords have even parity. The code {0000, 0011, 1100, 1111} meets that condition. The following graph 100 representation in FIG. 1 specifies the constraints on this code. In this example, the nodes c₁, c₂, c₃ and c₄ represent the digit nodes 105, 110, 115 and 120 respectively. Digit nodes represent the digits of the code. The other class of nodes (check nodes) represent the constraints on the code. In this example, the constraint is c₁+c₂+c₃+c₄=0 represented at 130.

Tanner Graph of a Code from it's Dual Code

A method to construct a Tanner graph for a systematic group code may be based on the foundations of the previous sections.

The symbol nodes of the Tanner graph represent the symbols of the code. If the code is a subgroup of Gⁿ, where G is isomorphic to [symbol] ᵢ₋₁^{m} Zₚ_{ᵢ}, the number of symbol nodes is mn. Check nodes are now described. By definition, each codeword in a code results in e* when its inner product is calculated with each codeword from its dual code. Or, ∀yεC^{⊥}∀xεC, [symbol] x,y [symbol] =e* where the inner product is calculated as shown in equation (9). Each codeword in yεC^{⊥} specifies a constraint of a type in equation (9) and would form a check node of the Tanner graph. The Tanner graph would have |C^{⊥}| check nodes, one for every codeword in C^{⊥}. Consider a codeword y=((y₁₁, . . . , y_{1,m}), . . . (y_{n,}1 . . . , y_{n,m}))εC^{⊥}. For every codeword x=((x₁₁, . . . , x_{1,m}), . . . (xn,₁, . . . , x_{n,m}))εC, the following constraint holds

$${\prod }_{i = 1}^{n} {\prod }_{j = 1}^{m} {λ}_{j}^{{x}_{i , j} {y}_{i , j}} = {e}^{*} \qquad ( 12 )$$

Edges are formed between a constraint node (represented by a constraint above) and a symbol node x_{i,j} if y_{i,j} is non-zero.

Reducing the Complexity of the Tanner Graph

The Tanner graph construction outlined above can be reduced in complexity by considering only those codewords as check nodes which are generators in C^{⊥}. This reduces the number of check nodes in the Tanner graph. Given the code C^{⊥}, an algorithm of linear computational complexity in n may be used to determine its generators. In this example, the generators of the code tabulated in Table 2 are {571, 624}. A theorem about using only generators of C^{⊥} as check nodes is now discussed.

Theorem 1 Let C^{⊥} (a dual code of C) be used to construct check nodes of a Tanner graph of a code C. Then, forming |C^{⊥}| check nodes, each with constraint as specified in equation (12) is equivalent to forming a Tanner graph with check nodes with only the generators of C^{⊥}.

Proof Let C^{⊥} be generated by the set {g₁, . . . , gₛ}. Each yεC^{⊥} can be written as [symbol] ᵢ₌₁^{s} gᵢu₁. Let xεC^{⊥} be an arbitrary codeword. Then, the constraint at check node y will be Πᵢ₌₁ⁿ Πⱼ₌₁^{m}λⱼ^{x}^{_{i,j}}^{y}^{_{i,j}}, which can be written as Πₙ₌₁ⁿ Πⱼ₌₁^{m} λⱼ^{x}^{_{i,j}}^{u}^{_{i,j}}^{g}^{_{i,j}} by resolving y into it's generators. This equation can be rearranged Πⱼ₌₁^{m} Πᵢ₌₁ⁿ λⱼ^{x}^{_{i,j}}^{u}^{ⱼ}^{g}^{_{i,j}}. The terms of product in terms of the generators which, by themselves are codewords in C^{⊥} are rearranged. Hence, their own inner products will result in e*. This reduces the previous equation to Πⱼ₌₁^{m} e*=e*.

It is evident that the converse of this proof also holds true, as the steps of the proof just stated can be shown to be true in reverse order. Hence, forming |C^{⊥}| constraints is equivalent to forming just ‘s’ constraint nodes from the generating set of C^{⊥}.

### Example 3

### The Tanner Graph of the (3,2) Code Defined in Equation (10)

If we consider the case of the systematic group code specified by the generator matrix in equation (10), the symbol nodes will consist of a length 3 sequence x=(x₁, x₂, x₃)εC as given in Table 1. However, each of x₁, x₂ and x₃ are isomorphic to some element of Z₂×Z₄. As x can be mapped to elements of that finite abelian group and x=(x₁, x₂, x₃) will become ((x₁₁, x₁₂), (x₂₁, x₂₂), (x₃₁, x₃₂)), each tuple an element in Z₂×Z₄. Therefore, this code will have six symbol nodes.

All the codewords of this code can be written as ((x₁₁, x₁₂), (x₂₁, x₂₂), (x₃₁, x₃₂)), each tuple an element in Z₂×Z₄. The dual of this code is generated by equation (11) and the codewords are shown in Table 2. The generators of this code are {571, 624}. Since each of these generators is orthogonal to all codewords in C, the check nodes will have constraints of the type (571, x)=e* and (624, x)=e*. Resolving x, 624 and 571 into the elements of Z₂×Z₄ to which they are isomorphic, we get (respectively) equation (12):

[symbol]

(12,02,10),(x₁₁x₁₂,x₂₁x₂₂,x₃₁x₃₂) [symbol] =e*

[symbol]

(11,13,01),(x₁₁x₁₂,x₂₁x₂₂,x₃₁x₃₂) [symbol] =e*

By reducing the constraints to the form shown in equation (12), we get

(−1)^{1.x}^{₁₁}(i)^{2.x}^{₁₂}(−1)^{0.x}^{₂₁}(i)^{2.x}^{_{2,2}}(−1)^{1.x}^{₃₁}(i)^{0.x}^{₃₂}=e*

(−1)^{1.x}^{₁₁}(i)^{1.x}^{₁₂}(−1)^{1.x}^{₂₁}(i)^{3.x}^{_{2,2}}(−1)^{0.x}^{₃₁}(i)^{1.x}^{₃₂}=e*

Since (−1)=i², we get the following equations which are the constraints. i^{2x}^{₁₁}^{+2x}^{₁₂}^{+2x}^{₂₂}^{+2x}^{₃₁}=e* and i^{2x}^{₁₁}^{+2x}^{₁₂}^{+2x}^{₂₁}^{+3x}^{₂₂}^{+x}^{₃₂}=e*. The Tanner graph looks as shown in FIG. 2 at 200, the constraint nodes c₁ at 210 and c₂ at 220 represent the constraints just obtained.

From the above discussions, algorithm 1 may be used to generate the minimal Tanner graph for a systematic group code C.

Algorithm 1
Algorithm for generating a Tanner graph for a systematic group code C

1. Given a generator matrix G (in the format specified as in equation(3)) for a systematic
group code C, determine the generator matrix of the dual code, represented as G′.
2. For all y = (x₁, . . . , xₙ₋ₖ) ∈ G^{n-k}, evaluate yG′ to determine the dual code C^{⊥}.
3. Determine the set of generators of C^{⊥}, represented as S_{C}_{^{⊥}}.
4. For each element of S_{C}_{^{⊥}}, determine the corresponding constraint (as specified in
equation(12)) which, serves as the corresponding constraint node in the Tanner graph.

A computer implemented method for generating a Tanner graph for a systematic group code C is illustrated at 300 in FIG. 3. For a given generator matrix for the systematic group code C, at 310, the generator matrix of the dual code is determined. At 320, the dual code is determined from the generator matrix. At 330, a set of generators for the dual code is determined. at 340, for each of the set of generators, a corresponding constraint is determined, and serves as a corresponding constraint in the resulting Tanner graph.

Computational Complexity of Algorithm 1

The computational complexity of the method is now described. Assuming that every arithmetic operation over the character group takes unit computational time (an assumption made in many works including), the step 1 of the algorithm takes r(1−r)n²(m²−m) steps, where r is the rate (k/n) of the n length group code. The step 2 of the algorithm takes 2r(1−r)n²m|C^{⊥}| steps, where |C^{⊥}| is the cardinality of the dual code of C. The step 3 of the algorithm is linear in n. It is noteworthy that for codes of rate r≈1, the computational complexity of this algorithm is arbitrarily low.

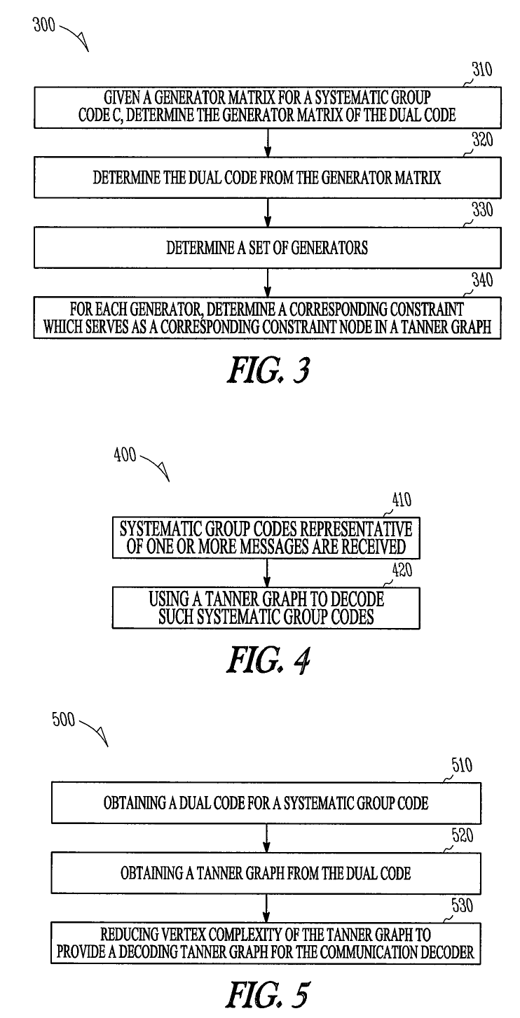

In one embodiment illustrated in FIG. 4, a method 400 of decoding messages is illustrated. At 410, systematic group codes representative of one or more messages are received. At 420, a Tanner graph is used to decode such systematic group codes.

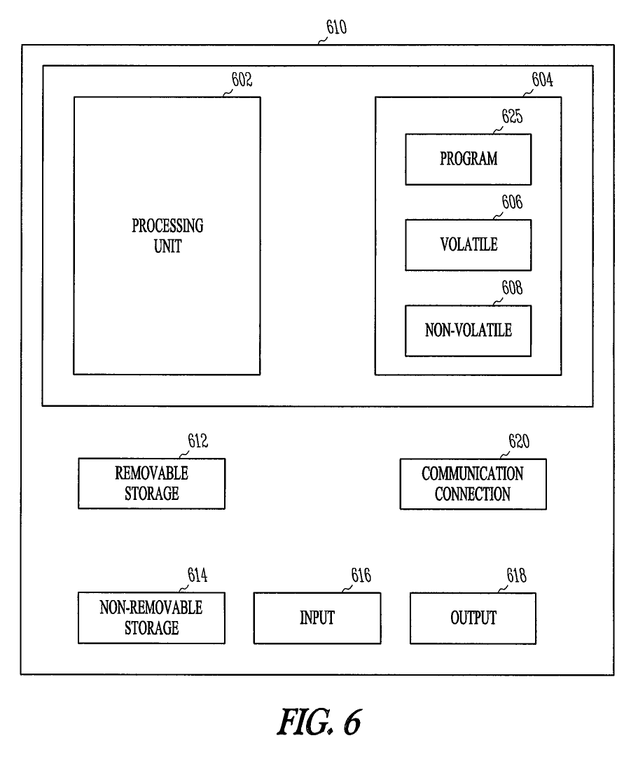

In a further embodiment, a method 500 of forming a communication decoder is illustrated in FIG. 5. At 510, a dual code for a systematic group code is obtained. At 520 a Tanner graph is obtained from the dual code. At 530, vertex complexity of the Tanner graph is reduced to provide a decoding Tanner graph for the communication decoder.

### CONCLUSION

For a restricted subset of group codes called systematic group codes, tractable and low complexity algorithms are possible. This is proved by describing one such algorithm to determine the Tanner graph of those codes.

A block diagram of a computer system that executes programming for performing the above algorithm is shown in FIG. 3. A general computing device in the form of a computer 310, may include a processing unit 302, memory 304, removable storage 312, and non-removable storage 314. Memory 304 may include volatile memory 306 and non-volatile memory 308. Computer 310 may include—or have access to a computing environment that includes—a variety of computer-readable media, such as volatile memory 306 and non-volatile memory 308, removable storage 312 and non-removable storage 314. Computer storage includes random access memory (RAM), read only memory (ROM), erasable programmable read-only memory (EPROM) & electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions. Computer 310 may include or have access to a computing environment that includes input 316, output 318, and a communication connection 320. The computer may operate in a networked environment using a communication connection to connect to one or more remote computers. The remote computer may include a personal computer (PC), server, router, network PC, a peer device or other common network node, or the like. The communication connection may include a Local Area Network (LAN), a Wide Area Network (WAN) or other networks.

Computer-readable instructions stored on a computer-readable medium are executable by the processing unit 302 of the computer 310. A hard drive, CD-ROM, and RAM are some examples of articles including a computer-readable medium.

The Abstract is provided to comply with 37 C.F.R. § 1.72(b) to allow the reader to quickly ascertain the nature and gist of the technical disclosure. The Abstract is submitted with the understanding that it will not be used to interpret or limit the scope or meaning of the claims.

1. A computer implemented method of communicating, the method comprising:
receiving systematic group codes representative of one or more messages;
using a Tanner graph to decode such systematic group codes.

2. The method of claim 1 wherein the Tanner graph enables decoding the group codes in polynomial time.

3. The method of claim 1 wherein the Tanner graph recursively specifies constraints which specify the code.

4. The method of claim 1 and further comprising determining a dual code from the group code.

5. The method of claim 4 wherein the Tanner graph is generated from the dual code.

6. The method of claim 4 and further comprising determining a set of generators from the dual code.

7. The method of claim 6 wherein the generators are orthogonal to all codewords in the group code.

8. The method of claim 7 wherein constraints of the Tanner graph are formed for each generator.

9. The method of claim 8 wherein constraints are formed in accordance with the following equation:
i^{2x}^{₁₁}^{+2x}^{₁₂}^{+2x}^{₂₂}^{+2x}^{₃₁}=e* and i^{2x}^{₁₁}^{2x}^{₁₂}^{+2x}^{₂₁}^{+3x}^{₂₂}^{+x}^{₃₂}=e*
where codewords are written as ((x₁₁, x₁₂), (x₂₁, x₂₂), (x₃₁, x₃₂)).

10. A method of forming a communication decoder comprising:
obtaining a dual code for a systematic group code;
obtaining a Tanner graph from the dual code; and
reducing vertex complexity of the Tanner graph to provide a decoding Tanner graph for the communication decoder.

11. The method of claim 10 wherein the Tanner graph comprises a first category of nodes that represent digits of the code words, and a second category of nodes represents constraints which the digits of the codewords obey.

12. The method of claim 10 wherein the Tanner graph recursively specifies constraints which specify the code.

13. The method of claim 10 and further comprising determining a dual code from the group code.

14. The method of claim 13 wherein the Tanner graph is generated from the dual code.

15. The method of claim 13 and further comprising determining a set of generators from the dual code.

16. The method of claim 16 wherein the generators are orthogonal to all codewords in the group code.

17. The method of claim 16 wherein constraints of the Tanner graph are formed for each generator.

18. The method of claim 17 wherein constraints are formed in accordance with the following equation:
i^{2x}^{₁₁}^{+2x}^{₁₂}^{+2x}^{₂₂}^{+2x}^{₃₁}=e* and i^{2x}^{₁₁}^{+2x}^{₁₂}^{+2x}^{₂₁}^{+3x}^{₂₂}^{+x}^{₃₂}=e*
where codewords are written as ((x₁₁, x₁₂), (x₂₁, x₂₂), (x₃₁, x₃₂)).

19. A system comprising:
a processor; and
a memory for storing processor executable code for causing the system to perform a method comprising:
obtaining a dual code for a systematic group code;
obtaining a Tanner graph from the dual code; and
reducing vertex complexity of the Tanner graph to provide a decoding Tanner graph for the communication decoder.

20. The system of claim 19 wherein the Tanner graph comprises a first category of nodes that represent digits of the code words, and a second category of nodes represents constraints which the digits of the codewords obey, and wherein the digits correspond to generators of a dual code derived from the code words that are orthogonal to all code words in the dual code and the group code.
